(19) United States
(12) Patent Application Publication
(10) Pub. No.: US 2024/0138230 A1
(43) Pub. Date: Apr. 25, 2024

(54) DISPLAY PANEL AND DISPLAY DEVICE

(71) Applicants: TCL CHINA STAR OPTOELECTRONICS TECHNOLOGY CO., LTD., Shenzhen, Guangdong (CN); HUIZHOU CHINA STAR OPTOELECTRONICS DISPLAY CO., LTD., Huizhou, Guangdong (CN)

(72) Inventors: Chao He, Shenzhen, Guangdong (CN); Shijian Qin, Shenzhen, Guangdong (CN)

(73) Assignees: TCL CHINA STAR OPTOELECTRONICS TECHNOLOGY CO., LTD., Shenzhen, Guangdong (CN); HUIZHOU CHINA STAR OPTOELECTRONICS DISPLAY CO., LTD., Huizhou, Guangdong (CN)

(21) Appl. No.: 17/755,001

(22) PCT Filed: Mar. 24, 2022
(86) PCT No.: PCT/CN2022/082987

§ 371 Date: Apr. 18, 2022

(30) Foreign Application Priority Data
Mar. 11, 2022 (CN) 202210239257.7

(51) Int. Cl. H10K 59/80

(52) U.S. Cl. CPC H10K 59/80522

(57) ABSTRACT

The present application discloses a display panel and a display device. The display panel includes a plurality of sub-pixels, a cathode, and an auxiliary electrode disposed in a layer different from the cathode. An extension length of the sub-pixel along the first direction is smaller than an extension length of the sub-pixel along the second direction, and the second direction intersects the first direction. The cathode contact hole is located between at least two adjacent rows of the sub-pixels, or the cathode contact hole is located between at least two adjacent columns of sub-pixels and extends along the first direction.

### BACKGROUND OF INVENTION

### Field of Invention

The present application relates to a field of printing technologies, and in particular, to a display panel and a display device.

### Description of Prior Art

Organic light-emitting diode (OLED) has advantages of all-solid-state, ultra-thin thickness, no viewing angle limitation, fast response time, self-illumination, long life, energy saving, and environmental protection, and is unanimously recognized as the mainstream technology of the next generation display. There are two common methods for making light-emitting layers in OLEDs, that is, vapor deposition and inkjet printing. Inkjet printing has the advantages of high material utilization rate and low equipment investment cost, and is a very promising printing method.

At present, in the OLED display panel, in order to solve the problem that resistance of a cathode is large and prone to voltage drop in a top light emission mode, an auxiliary electrode is provided, and the auxiliary electrode is electrically connected to the cathode through a cathode contact hole, so as to reduce resistance of the cathode and improve brightness uniformity of a panel. However, arrangement of the cathode contact holes in the prior art reduces an effective printing range of sub-pixels, thus increasing printing time.

### SUMMARY OF INVENTION

The present application provides a display panel and a display device to solve technical problems in the prior art that arrangement of the cathode contact holes leads to reduction of an effective printing range and an increase of printing time.

The present application provides a display panel, which includes a cathode and an auxiliary electrode arranged in a layer different from the cathode, wherein the auxiliary electrode is electrically connected to the cathode through a corresponding one of cathode contact holes, the display panel further disposes a plurality of sub-pixels arranged in an array, an extension length of each of the sub-pixels along a first direction is less than an extension length of each of the sub-pixels along a second direction, and the second direction intersects the first direction; and

wherein one of the cathode contact holes is defined between at least two adjacent rows of the sub-pixels and extends along the second direction, or one of the cathode contact holes is located between at least two adjacent columns of the sub-pixels and extends along the first direction.

Optionally, in some embodiments of the present application, one of the cathode contact holes is located between at least two adjacent rows of the sub-pixels, and an extension length of each of the cathode contact holes along the second direction is equal to the extension length of at least one of the sub-pixels along the second direction.

Optionally, in some embodiments of the present application, at least one of the cathode contact holes disposes a first portion and at least one second portion, the first portion extends along the second direction, each of the second portion extends from the first portion along the first direction, and the second portion is located between adjacent ones of the columns of the sub-pixels.

Optionally, in some embodiments of the present application, a plane structure of the second portion has a shape of a triangle, a circular arc, a rectangle, or a trapezoid.

Optionally, in some embodiments of the present application, each of the sub-pixels corresponds to one of the cathode contact holes.

Optionally, in some embodiments of the present application, the sub-pixels are red sub-pixels, green sub-pixels, or blue sub-pixels; the red sub-pixels, the green sub-pixels, and the blue sub-pixels are repeatedly arranged in any combination as repeating units; and
each of the repeating units is correspondingly provided with one of the cathode contact holes.

Optionally, in some embodiments of the present application, an extension length of each of the red sub-pixels in the second direction, an extension length of each of the green sub-pixels in the second direction, and an extension length of each of the blue sub-pixels in the second direction are all equal, and the extension length of each of the red sub-pixels along the first direction is greater than the extension length of each of the green sub-pixels along the first direction length, the extension length of each of the blue sub-pixels along the first direction is greater than the extension length of each of the red sub-pixels along the first direction.

Optionally, in some embodiments of the present application, the cathode contact holes are disposed between the red sub-pixels and the green sub-pixels.

Optionally, in some embodiments of the present application, the cathode contact holes are disposed between the blue sub-pixels and the red sub-pixels, or the cathode contact holes are disposed in the blue sub-pixels and the green sub-pixels;

a side of each of the blue sub-pixels close to the cathode contact holes has a concave portion, and at least part of each of the cathode contact holes is disposed in the concave portion.

Optionally, in some embodiments of the present application, the cathode contact holes are located between at least two adjacent columns of the sub-pixels, and an extension length of each of the cathode contact holes along the first direction is equal to an extension length of each of the sub-pixels along the first direction.

Optionally, in some embodiments of the present application, at least one of the cathode contact holes disposes a first portion and at least one second portion, the first portion extends along the first direction, each of the second portion extends from the first portion along the second direction, and the second portion is located between adjacent ones of the columns of the sub-pixels.

Optionally, in some embodiments of the present application, an extension length of each of the cathode contact holes along the first direction is equal to an extension length of a row of the sub-pixels along the first direction, and one of the cathode contact holes is defined correspondingly in every adjacent three columns of the sub-pixels.

Correspondingly, the present application also provides a display device, which includes a power supply chip and a display panel, wherein the display panel disposes a cathode and an auxiliary electrode arranged in a layer different from the cathode, wherein the auxiliary electrode is electrically connected to the cathode through a corresponding one of cathode contact holes, the display panel further disposes a plurality of sub-pixels arranged in an array, an extension length of each of the sub-pixels along a first direction is less than an extension length of each of the sub-pixels along a second direction, and the second direction intersects the first direction;
wherein one of the cathode contact holes is defined between at least two adjacent rows of the sub-pixels and extends along the second direction, or one of the cathode contact holes is located between at least two adjacent columns of the sub-pixels and extends along the first direction; and
wherein the power supply chip is connected to the display panel to provide a common voltage to the cathode.

Optionally, in some embodiments of the present application, one of the cathode contact holes is located between at least two adjacent rows of the sub-pixels, and an extension length of each of the cathode contact holes along the second direction is equal to the extension length of at least one of the sub-pixels along the second direction.

Optionally, in some embodiments of the present application, at least one of the cathode contact holes disposes a first portion and at least one second portion, the first portion extends along the second direction, each of the second portion extends from the first portion along the first direction, and the second portion is located between adjacent ones of the columns of the sub-pixels.

Optionally, in some embodiments of the present application, each of the sub-pixels corresponds to one of the cathode contact holes.

Optionally, in some embodiments of the present application, the sub-pixels are red sub-pixels, green sub-pixels, or blue sub-pixels; the red sub-pixels, the green sub-pixels, and the blue sub-pixels are repeatedly arranged in any combination as repeating units; and
each of the repeating units is correspondingly provided with one of the cathode contact holes.

Optionally, in some embodiments of the present application, an extension length of each of the red sub-pixels in the second direction, an extension length of each of the green sub-pixels in the second direction, and an extension length of each of the blue sub-pixels in the second direction are all equal, and the extension length of each of the red sub-pixels along the first direction is greater than the extension length of each of the green sub-pixels along the first direction length, the extension length of each of the blue sub-pixels along the first direction is greater than the extension length of each of the red sub-pixels along the first direction.

Optionally, in some embodiments of the present application, the cathode contact holes are disposed between the blue sub-pixels and the red sub-pixels, or the cathode contact holes are disposed in the blue sub-pixels and the green sub-pixels;
a side of each of the blue sub-pixels close to the cathode contact holes has a concave portion, and at least part of each of the cathode contact holes is disposed in the concave portion.

Optionally, in some embodiments of the present application, the cathode contact holes are located between at least two adjacent columns of the sub-pixels, and an extension length of each of the cathode contact holes along the first direction is equal to an extension length of each of the sub-pixels along the first direction.

The present application discloses a display panel and a display device. The display panel includes a cathode and an auxiliary electrode disposed in a layer different from the cathode, and the auxiliary electrode is electrically connected to the cathode through a corresponding one of the cathode contact holes. The display panel further includes a plurality of sub-pixels, and the plurality of the sub-pixels are arranged in an array. Since an extension length of the sub-pixels along the first direction is smaller than an extension length of the sub-pixel along the second direction, according to a relationship of the printing logic algorithm, only nozzles overlapping each other in the second direction (a long axis direction of the sub-pixel) can perform inkjet printing when passing through the sub-pixel. Therefore, in the present application, the cathode contact holes are disposed between two adjacent rows of sub-pixels and extend in the second direction, or the cathode contact holes are disposed between two adjacent columns of sub-pixels and extend in the first direction. On the one hand, when inkjet printing is performed along the second direction, a printing range corresponding to each of the sub-pixels is effectively guaranteed, thereby improving the utilization rate of the printing nozzles and reducing the inkjet printing time. On the other hand, the cathode contact holes are extended along the first direction or the second direction, which can effectively enlarge the cathode contact holes and further reduce the resistance of the cathode.

### BRIEF DESCRIPTION OF DRAWINGS

In order to more clearly illustrate the technical solutions of the embodiments of the application, the drawings illustrating the embodiments will be briefly described below. Obviously, the drawings in the following description merely illustrate some embodiments of the present invention. Other drawings may also be obtained by those skilled in the art according to these figures without paying creative work.

FIG. 1 is a schematic diagram of a first plane structure of a display panel provided by the present application.

FIG. 2 is a schematic diagram of a cross-sectional structure of the display panel shown in FIG. 1 provided by the present application along line AA′.

FIG. 3 is a schematic diagram of a principle of inkjet printing performed on a display panel provided by the present application.

FIG. 4 is a schematic diagram of a second plane structure of the display panel provided by the present application.

FIG. 5 is a schematic diagram of a third plane structure of the display panel provided by the present application.

FIG. 6 is a schematic diagram of a fourth plane structure of the display panel provided by the present application.

FIG. 7 is a schematic diagram of a fifth plane structure of the display panel provided by the present application.

FIG. 8 is a schematic diagram of a sixth plane structure of the display panel provided by the present application.

FIG. 9 is a schematic diagram of a seventh plane structure of the display panel provided by the present application.

FIG. 10 is a schematic diagram of an eighth plane structure of the display panel provided by the present application.

FIG. 11 is a schematic diagram of a ninth plan structure of the display panel provided by the present application.

FIG. 12 is a schematic diagram of a structure of the display device provided by the present application.

### DETAILED DESCRIPTION OF PREFERRED EMBODIMENTS

The technical solutions in the embodiments of the present application will be clearly and completely described in the following with reference to the accompanying drawings in the embodiments. It is apparent that the described embodiments are only a part of the embodiments of the present application, and not all of them. All other embodiments obtained by a person skilled in the art based on the embodiments of the present application without creative efforts are within the scope of the present application. In addition, it should be understood that the specific implementations described here are only used to illustrate and explain the application, and are not used to limit the application. In the present application, unless otherwise stated, the orientation words used such as “upper” and “lower” generally refer to the upper and lower directions of the device in actual use or working state, and specifically refer to the drawing directions in the drawings, while “inner” and “outer” refer to the outline of the device.

The present application provides a display panel and a display device, which will be described in detail below. It should be noted that the order of description in the following embodiments is not intended to limit the preferred order of the embodiments. In addition, in the following embodiments, the description of ach embodiment has its own emphasis. The parts that are not described in detail in an embodiment can be referred to the detailed descriptions in other embodiments.

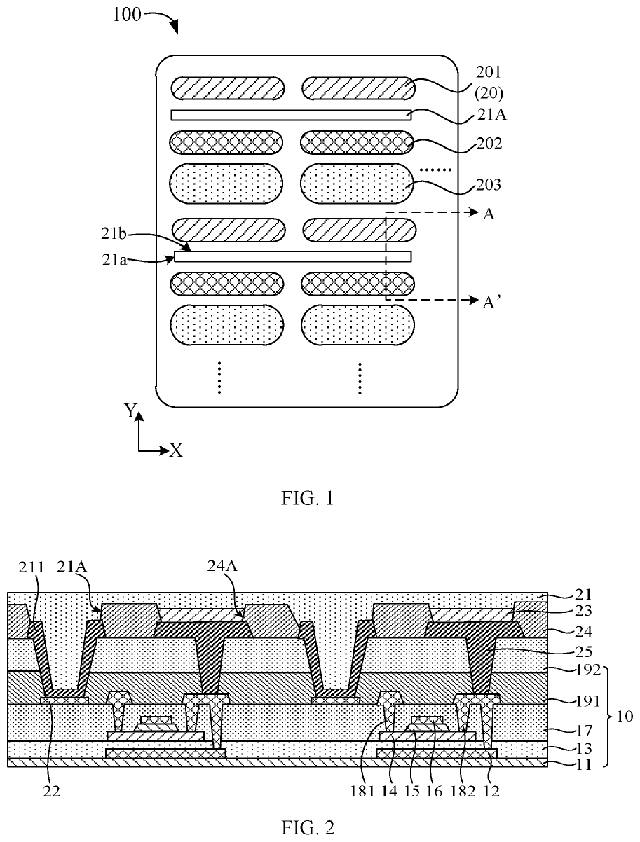

Referring to FIG. 1 and FIG. 2, FIG. 1 is a schematic diagram of a first plane structure of the display panel provided by the present application; and FIG. 2 is a schematic diagram of a cross-sectional structure of the display panel shown in FIG. 1 provided in the present application along line AA′. In an embodiment of the present application, the display panel 100 includes the cathode 21 and the auxiliary electrode 22 disposed in a layer different from the cathode 21. The auxiliary electrode 22 is electrically connected to the cathode 21 through the corresponding cathode contact hole 21A. The display panel 100 also includes a plurality of sub-pixels 20. The plurality of sub-pixels 20 are arranged in an array. An extension length of the sub-pixels 20 in the first direction is smaller than an extension length of the sub-pixels 20 in the second direction. The second direction intersects the first direction.

The cathode contact holes 21A are located between at least two adjacent rows of sub-pixels 20 and extend along the second direction. Alternatively, the cathode contact holes 21A are located between at least two adjacent columns of sub-pixels 20 and extend along the first direction.

The first direction is a direction extending along the Y axis, and the second direction is a direction extending along the X axis. The first direction and the second direction may intersect each other vertically, or may only intersect but not be perpendicular to each other, and may be specifically set according to the arrangement of the sub-pixels 20. Of course, in some embodiments, the second direction may also be a direction extending along the Y axis, and the first direction may be a direction extending along the X axis. It should be noted that, in the embodiments of the present application, it is taken as an example that the first direction is the direction extending along the Y axis and the second direction is the direction extending along the X axis, which should not be construed as a limitation of the present application.

The connection through the cathode contact hole 21A means that the cathode contact hole 21A is provided with a conductive material therein, which is equivalent to the connection through a connection wire. That is, the cathode 21 being connected to the auxiliary electrode 22 through the cathode contact hole 21A means that the cathode 21 is electrically connected to the auxiliary electrode 22 through the connection wire provided in the cathode contact hole 21A.

When the cathode contact holes 21A extend along the second direction, the cathode contact holes 21A may be located between two adjacent rows of sub-pixels 20 or between three or more adjacent rows of sub-pixels 20. When the cathode contact holes 21A extend along the first direction, the cathode contact holes 21A may be located between two adjacent columns of sub-pixels 20, or may be located between three or more adjacent columns of sub-pixels 20. Details will be introduced in the following embodiments, which will not be repeated herein for brevity.

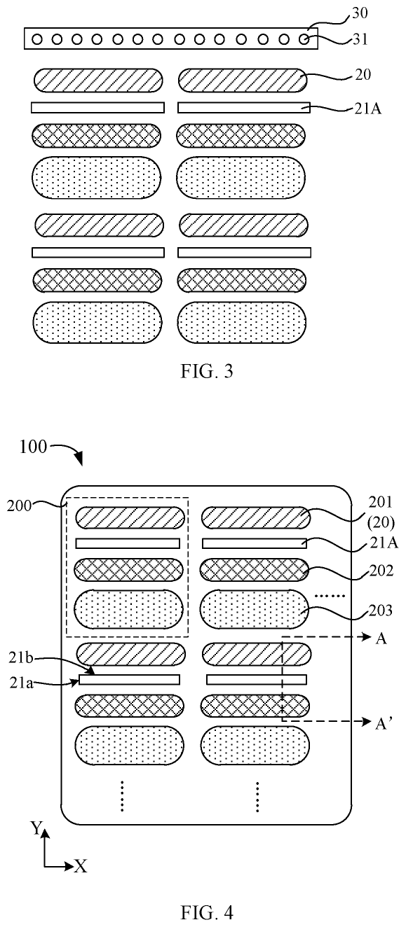

Referring to FIG. 3, FIG. 3 is a schematic diagram of a principle of inkjet printing on a display panel provided by the present application. Inkjet printing often uses an inkjet printing device (not shown). The inkjet printing device includes a plurality of printheads 30. Only one of the printheads 30 is shown in FIG. 3 for illustration, which should not be construed as a limitation on the present application. Generally, for consideration of printing stability, the printhead 30 is fixed, and the display panel 100 moves along a direction perpendicular to a printing direction.

Each printhead 30 includes a plurality of nozzles 31. The printhead 30 discharges a printing material through a plurality of nozzles 31 to print the display panel 100 to be formed. For example, when an inkjet printing device is used to print the light-emitting layer 23 of the display panel 100, the printing material may be a red light-emitting material, a green light-emitting material, a blue light-emitting material, a white light-emitting material, or the like.

It is appreciated that since the extension length of the sub-pixels 20 in the second direction is greater than the extension length of the sub-pixels 20 in the first direction, according to a relationship of the printing logic algorithm, only nozzles 31 overlapping each other in the second direction (a long axis direction of the sub-pixel 20) can perform inkjet printing when passing through the sub-pixels 20.

Therefore, in an embodiment of the present application, by disposing the cathode contact holes 21A between two adjacent rows of sub-pixels 20 and extending the cathode contact holes 21A along the second direction, the cathode contact holes 21A do not occupy the extension space of the sub-pixels 20 in the second direction. On the basis that the pixel resolution of the display panel 100 is constant, the extension length of each sub-pixel 20 along the second direction can be maximized, which ensures the printing range corresponding to each sub-pixel 20 when inkjet printing is performed along the second direction. Thus, the utilization rate of the nozzles 31 is improved, and the inkjet printing time is reduced.

Alternatively, in an embodiment of the present application, the cathode contact holes 21A are disposed between two adjacent columns of sub-pixels 20 and extend along the first direction, so that the ends of the plurality of sub-pixels 20 that are close to the cathode contact hole 21A and located in the same column can be flush with the ends close to the cathode contact hole 21A. That is, in an embodiment of the present application, a small amount of the extension length of each sub-pixel 20 along the second direction is sacrificed, which also effectively ensures the printing range corresponding to each sub-pixel 20 during inkjet printing in the second direction, thereby improving the utilization of printing nozzles, reducing inkjet printing time. In this case, the extension length of each sub-pixel 20 along the first direction is not affected, so the pixel density can be increased in the first direction.

In an embodiment of the present application, the display panel 100 includes, but is not limited to, the array substrate 10, the anode 25, the pixel definition layer 24, and the light-emitting layer 23.

The anode 25 is disposed on the array substrate 10. The pixel definition layer 24 is disposed on a side of the anode 25 away from the array substrate 10. The pixel definition layer 24 is provided with an opening 24A and a cathode contact hole 21A. The cathode contact hole 21A penetrates the pixel definition layer 24 and extends to the auxiliary electrode 22. The cathode contact hole 21A exposes a side surface of the auxiliary electrode 22 away from the array substrate 10. The opening 24A exposes a side surface of the anode 25 away from the array substrate 10. The light-emitting layer 23 is provided in the opening 24A. The cathode 21 is disposed on a side of the light-emitting layer 23 away from the array substrate 10. The auxiliary electrode 22 is disposed on a side of the cathode 21 close to the array substrate 10.

Specifically, the array substrate 10 includes, but is not limited to, the substrate 11, the light-shielding layer 12 disposed on the substrate 11, the buffer layer 13 disposed on the substrate 11 and covering the light-shielding layer 12, which are sequentially stacked and disposed on the buffer layer from bottom to top. The active layer 14, the gate insulating layer 15 and the gate 16 on the layer 13 are disposed above the buffer layer 13 and cover the active layer 14, the gate insulating layer 15 and the interlayer dielectric layer 17 of the gate 16. The active layer 14 includes a channel region and a source region and a drain region located on both sides of the channel region. The source electrode 181 provided on the interlayer dielectric layer 17 is electrically connected to the source electrode region. The drain electrode 182 disposed on the interlayer dielectric layer 17 is electrically connected to the drain region. The drain electrode 182 is electrically connected to the light-shielding layer 12 to prevent the voltage change on the light-shielding layer 12 from affecting the electrical properties of the active layer 14. The source electrode 181 and the drain electrode 182 are also covered with a passivation layer 191 and a planarization layer 192 which are stacked and arranged. The anode 25 is provided on the planarization layer 192.

The auxiliary electrode 22 is disposed in a same layer as the source electrode 181 and the drain electrode 182, so as to reduce the manufacturing process. The auxiliary electrodes 22 are disposed between adjacent sub-pixels 20. The cathode contact hole 21A penetrates through the pixel definition layer 24 and the passivation layer 191 and extends to the planarization layer 192 to expose a side surface of the auxiliary electrode 22 close to the cathode 21. The cathode 21 is electrically connected to the auxiliary electrode 22 through the cathode contact hole 21A. A plurality of auxiliary electrodes 22 may be provided, or the auxiliary electrode 22 may be provided in a form of a mesh structure as a whole.

Further, in some embodiments of the present application, a conductive layer 211 is provided in the cathode contact hole 21A. The conductive layer 211 is provided in a same layer as the anode 25. Therefore, the conductive layer 211 and the anode 25 can be obtained by patterning the same metal layer, which further reduces the resistance of the cathode 21 while simplifying the process.

Of course, the cross-sectional structure of the display panel 100 shown in FIG. 2 is only to facilitate understanding of the relationship between the cathode 21, the auxiliary electrode 22, and the cathode contact hole, and should not be construed as a limitation of the present application. In some embodiments of the present application, the auxiliary electrode 22 may also be arranged at other positions. For example, the auxiliary electrode 22 is disposed in a same layer as the light-shielding layer 12, the auxiliary electrode 22 is disposed in the planarization layer 192, and the auxiliary electrode 22 and the anode 25 are disposed in a same layer, which are not specifically limited in the present application.

In an embodiment of the present application, the cathode 21 may be made of a high-conductivity material. The high-conductivity material may be any of silver (Ag), aluminum (Al), or magnesium (Mg)/Ag.

Further, if the display panel 100 provided by an embodiment of the present application is a top emission display panel, the thickness of the cathode 21 is set to be thinner, which can reduce the influence of the cathode 21 on the light transmittance. In this case, a sheet resistance of the cathode 21 is relatively large, and a voltage drop problem is likely to occur. The material of the auxiliary electrode 22 may be a conductor such as indium tin oxide, indium zinc oxide, copper, aluminum, molybdenum, titanium, etc., or alloys thereof. The above-mentioned materials have good electrical conductivity and can effectively reduce the impedance of the cathode 21 electrically connected to the auxiliary electrode 22.

In an embodiment of the present application, the cathode 21 may be a surface cathode, that is, the entire surface covers all the light-emitting layers 23. In this case, since the cathode 21, the auxiliary electrode 22, and the cathode contact hole 21A are all equipotential, they can be short-circuited. Therefore, part of the cathode contact holes 21A may be provided in the display panel 100, thereby reducing the area occupied by the cathode contact holes 21A and facilitating the improvement of the pixel resolution of the display panel 100. Of course, in other embodiments of the present application, patterned cathodes 21 may be provided according to requirements. For example, each sub-pixel 20 or a plurality of sub-pixels 20 may be provided with an independent cathode 21 correspondingly. In this case, one auxiliary electrode 22 and one cathode contact hole 21A may be provided corresponding to each cathode 21.

In an embodiment of the present application, the material of the light-emitting layer 23 may be an organic light-emitting material or an inorganic quantum material. The organic light-emitting material or the inorganic quantum material is a technology well known to those skilled in the art, and details are not described herein again. The light-emitting layer 23 can emit light of different colors such as red light, green light, blue light, yellow light, and white light. The light-emitting layer 23 is formed by printing the above-mentioned organic light-emitting material or inorganic quantum material in the opening 24A.

Specifically, referring to FIG. 1, in an embodiment of the present application, the cathode contact hole 21A is located between at least two adjacent rows of sub-pixels 20. The extension length of each cathode contact hole 21A along the second direction is equal to the extension length of at least one sub-pixel 20 along the second direction.

The extension length of each cathode contact hole 21A along the second direction may be equal to the extension length of one sub-pixel 20 along the second direction. The extension length of each cathode contact hole 21A in the second direction may be equal to the extension length of the two sub-pixels 20 in the second direction. The extension length of each cathode contact hole 21A in the second direction may be equal to the extension length of one row of sub-pixels 20 in the second direction. The present application is not specifically limited to the above. When each cathode contact hole 21A is disposed corresponding to a plurality of sub-pixels 20, the plurality of auxiliary electrodes 22 can be electrically connected to the cathode 21 through a same cathode contact hole 21A. An auxiliary electrode 22 with a larger area may also be provided corresponding to the same cathode contact hole 21A.

For example, as shown in FIG. 1, the extension length of each cathode contact hole 21A along the second direction is equal to the extension length of one row of sub-pixels 20 along the second direction, and each cathode contact hole 21A is located between three adjacent rows of sub-pixels 20. That is, every three rows of sub-pixels 20 share one cathode contact hole 21A.

In an embodiment of the present application, the cathode contact hole 21A is extended along the second direction, which can effectively increase a planar area of the cathode contact hole 21A. It can be seen from the foregoing analysis that, in an embodiment of the present application, the connection between the cathode 21 and the auxiliary electrode 22 through the cathode contact hole 21A means that the cathode 21 and the auxiliary electrode 22 are electrically connected through the connection wire disposed in the cathode contact hole 21A. The planar area of the cathode contact hole 21A represents the cross-sectional area of the connection wire. The larger the cross-sectional area of the connection wire, the smaller the resistance of the connection wire, and the smaller the effect of the voltage drop caused by the cathode 21.

Specifically, in some embodiments of the present application, the plane structure of the cathode contact hole 21A includes a first side edge 21a and a second side edge 21b arranged adjacently. The length of the first side 21a is 2 to 5 micrometers. The length of the second side edge 21b is 100 micrometers to 10 millimeters. For example, the length of the first side 21a may be 2 micrometers, 2.5 micrometers, 3 micrometers, 4 micrometers, 5 micrometers, or the like. The length of the second side edge 21b is 100 micrometers, 500 micrometers, 1 mm, 5 mm, 8 mm, 9 mm, 10 mm, or the like.

In some embodiments of the present application, each sub-pixel 20 may be correspondingly provided with a cathode contact hole 21A. As such, the distribution uniformity of the cathode contact holes 20A and the auxiliary electrodes 22 can be maintained.

Further, in an embodiment of the present application, the sub-pixel 20 includes a red sub-pixel 201, a green sub-pixel 202, and a blue sub-pixel 203. The red sub-pixels 201, the green sub-pixels 202, and the blue sub-pixels 203 are repeatedly arranged in any combination as repeating units 200. Each of the repeating units 200 is correspondingly provided with one of the cathode contact holes 20A.

Specifically, the red sub-pixels 201, the green sub-pixels 202, and the blue sub-pixels 203 may be arranged in any one of sequences, such as RGB, RBG, BGR, BRG, GRB, GBR, etc., as the repeating units 200, and the present application is not specifically limited thereto.

Referring to FIG. 4, FIG. 4 is a schematic diagram of a second plane structure of the liquid crystal display panel provided by the present application. The difference from the liquid crystal display panel 100 shown in FIG. 1 is that one cathode contact hole 20A is provided corresponding to one repeating unit 200 in this embodiment of the present application. Correspondingly, each repeating unit 200 is provided with an auxiliary electrode 22 correspondingly. Therefore, on the basis of reducing the cathode contact holes 20A and the auxiliary electrodes 22, the distribution uniformity of the cathode contact holes 20A and the auxiliary electrodes 22 can be maintained, and the display uniformity of the display panel 100 can be improved.

In each repeating unit 200, the cathode contact hole 20A may be disposed between the red sub-pixel 201 and the green sub-pixel 202. The cathode contact hole 20A may also be provided between the green sub-pixel 202 and the blue sub-pixel 203. The cathode contact hole 20A may also be provided between the red sub-pixel 201 and the blue sub-pixel 203.

Further, in an embodiment of the present application, the colors of each row of the sub-pixels 20 are the same. Each column of sub-pixels 20 is repeatedly arranged in the same repeating unit 200. Therefore, each printhead 30 can print only one type of printing material, so as to avoid color mixing and improve the printing effect.

Of course, the present application is not limited thereto. For example, in some embodiments, the colors of the sub-pixels 20 in each column may be the same, and each row of the sub-pixels 20 are repeatedly arranged in the same repeating unit 200.

In some embodiments of the present application, the extension length of each red sub-pixel 201 along the second direction, the extension length of each green sub-pixel 202 along the second direction, and the extension length of each blue sub-pixel 203 along the second direction are equal. The extension length of each red sub-pixel 201 along the first direction is greater than the extension length of each green sub-pixel 202 along the first direction. The extension length of each blue sub-pixel 203 along the first direction is greater than the extension length of each red sub-pixel 201 along the first direction.

It is appreciated, due to the characteristics of the RGB materials, the light-emitting brightness of the green light-emitting layer is higher than that of the red light-emitting layer. The emission luminance of the red light-emitting layer is higher than that of the blue light-emitting layer. Therefore, in an embodiment of the present application, the extension length of each red sub-pixel 201 in the second direction, the extension length of each green sub-pixel 202 in the second direction, and the extension length of each blue sub-pixel 203 in the second direction are all equal, the printing range corresponding to each sub-pixel 20 can be guaranteed when inkjet printing is performed along the second direction, thereby improving the utilization rate of the nozzles 31. Meanwhile, the extension length of each red sub-pixel 201 along the first direction is set greater than the extension length of each green sub-pixel 202 along the first direction, and the extension length of each blue sub-pixel 203 along the first direction is greater than that of each red sub-pixel 201 along the first direction, so that the light-emitting area of the red sub-pixel 201 is larger than that of the green sub-pixel 202, and the light-emitting area of the blue sub-pixel 203 is larger than that of the red sub-pixel 201, thereby ensuring the uniformity of light emission of the display panel 100.

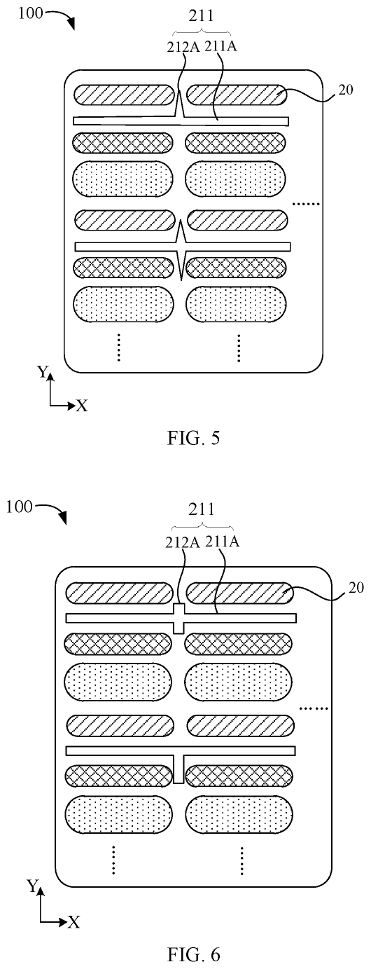

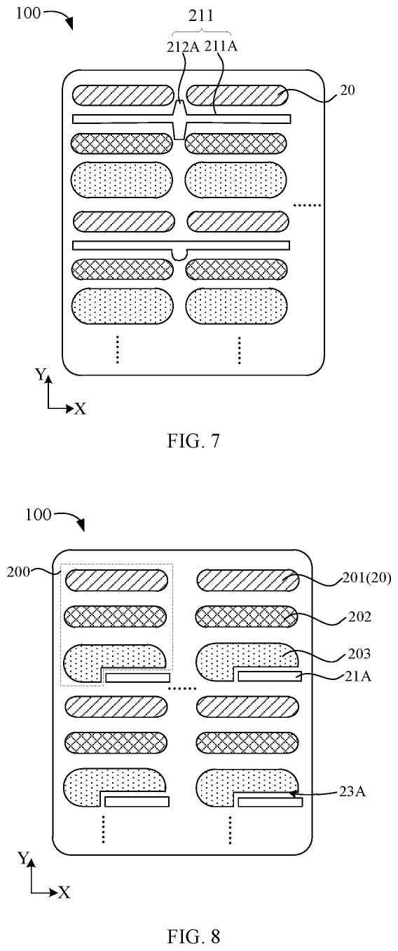

Referring to FIGS. 5-7, FIG. 5 is a schematic diagram of a third plane structure of the display panel provided by the present application; FIG. 6 is a schematic diagram of a fourth plane structure of the display panel provided by the present application; and FIG. 7 is a schematic diagram of a fifth plane structure of the display panel provided by the present application. The difference from the display panel 100 shown in FIG. 1 is that, in this embodiment of the present application, at least one cathode contact hole 21A includes a first portion 211A and at least one second portion 212A. The first portion 211A extends in the second direction. The second portion 212A extends in the first direction from the first portion 211A. The second portion 212A is located between two adjacent columns of sub-pixels 20.

It is appreciated, without impacting a printing area, the area of the cathode contact hole 21A can be increased by arranging the second portion 212A at a gap between the adjacent sub-pixels 20. In this way, the extension length of the first portion 211A in the first direction can be reduced. While reducing the impedance of the cathode 21, the space occupied by the first portion 211A in the first direction is reduced, thereby improving pixel resolution.

Further, in an embodiment of the present application, the plane structure of the second portion 212A may be in a shape of a triangle, a circular arc, a rectangle, a trapezoid, or the like. As shown in FIG. 5, the plane structure of the second portion 212A has a shape of a triangle. As shown in FIG. 6, the plane structure of the second portion 212A has a shape of a rectangle. As shown in FIG. 7, the plane structure of the second portion 212A has a shape of a trapezoid or a circular arc. Of course, the plane structure of the second portion 212A in an embodiment of the present application is not limited thereto. The plane structure of the second portion 212A can be designed according to the topography of the gap between adjacent sub-pixels 20, and the area of the cathode contact hole 21A can be increased without impacting the printing area.

Referring to FIG. 8, FIG. 8 is a schematic diagram of a sixth plane structure of the display panel provided by the present application. The difference from the display panel 100 shown in FIG. 1 is that, in an embodiment of the present application, the cathode contact hole 21A is disposed between the blue sub-pixel 203 and the red sub-pixel 201, or the cathode contact hole 21A is disposed between the sub-pixel 203 and the green sub-pixel 202. A side of the blue sub-pixel 203 close to the cathode contact hole 21A has a concave portion 23A. At least part of the cathode contact hole 21A is provided in a concave portion 23A.

The extension length of each red sub-pixel 201 along the second direction, the extension length of each green sub-pixel 202 along the second direction, and the extension length of each blue sub-pixel 203 along the second direction are equal. The extension length of each red sub-pixel 201 along the first direction is greater than the extension length of each green sub-pixel 202 along the first direction. The extension length of each blue sub-pixel 203 along the first direction is greater than the extension length of each red sub-pixel 201 along the first direction.

The embodiments of the present application are described by taking the example that the cathode contact hole 21A is disposed between the blue sub-pixel 203 and the red sub-pixel 201. The concave portion 23A is recessed from a side of the blue sub-pixel 203 close to the red sub-pixel 201 to a side of the blue sub-pixel 203 away from the red sub-pixel 201. The concave portion 23A may be provided at an edge of the blue sub-pixel 203 or may be provided at a middle of the blue sub-pixel 203. In an embodiment of the present application, the entire cathode contact hole 21A may be disposed in the concave portion 23A. Alternatively, in an embodiment of the present application, a part of the cathode contact hole 21A may be provided in the concave portion 23A.

It is appreciated, in order to ensure the uniformity of light emission of the display panel 100, the extension length of the blue sub-pixels 203 along the first direction is relatively long. Therefore, in an embodiment of the present application, the blue sub-pixel 203 is set as a special-shaped structure having the concave portion 23A. Then, at least a part of the cathode contact hole 21A is provided in the concave portion 23A. On the one hand, the printing range corresponding to the blue sub-pixel 203 can be guaranteed when inkjet printing is performed along the second direction. On the other hand, the extension length of each sub-pixel 20 along the first direction is not impacted, so the pixel density can be increased in the first direction.

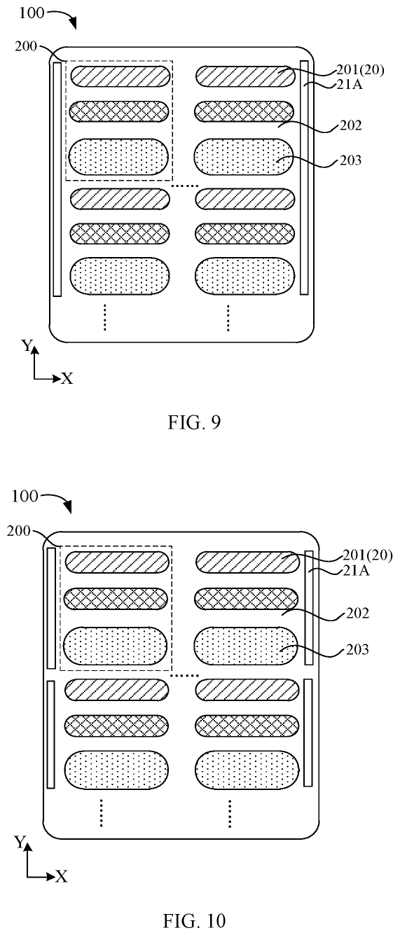

Referring to FIG. 9, FIG. 9 is a schematic diagram of a seventh plane structure of the display panel provided by the present application. The difference from the display panel 100 shown in FIG. 1 is that, in this embodiment of the present application, the cathode contact holes 21A are located between at least two adjacent columns of sub-pixels 20. The extension length of each cathode contact hole 21A along the first direction is equal to the extension length of the at least one sub-pixel 20 along the first direction.

Each cathode contact hole 21A may be located between every two adjacent columns of sub-pixels 20.

The extension length of each cathode contact hole 21A along the first direction may be equal to the extension length of one sub-pixel 20 along the first direction. The extension length of each cathode contact hole 21A in the first direction may be equal to the extension length of the two sub-pixels 20 in the first direction. The extension length of each cathode contact hole 21A along the first direction may be equal to the extension length of one column of sub-pixels 20 along the first direction. The present application is not specifically limited the above situations. When each cathode contact hole 21A is disposed corresponding to a plurality of sub-pixels 20, the plurality of auxiliary electrodes 22 can be electrically connected to the cathode 21 through a same cathode contact hole 21A. An auxiliary electrode 22 with a larger area may also be provided corresponding to the same cathode contact hole 21A.

In an embodiment of the present application, the cathode contact hole 21A is extended along the first direction, which can effectively increase the plane area of the cathode contact hole 21A. As such, the resistance of the cathode 21 electrically connected to the auxiliary electrode 22 through the cathode contact hole 21A is reduced. In addition, the extension length of each sub-pixel 20 in the first direction is not affected by the cathode contact hole 21A, so the pixel density can be increased in the first direction.

Further, in some embodiments of the present application, the extension length of each cathode contact hole 21A along the first direction is equal to the extension length of one column of sub-pixels 20 along the first direction, and every three adjacent columns of sub-pixels 20 is provided with a corresponding one cathode contact hole 20A.

It is appreciated, in an embodiment of the present application, the cathode contact hole 21A is disposed between two adjacent columns of sub-pixels 20, and the extension length of each sub-pixel 20 in the second direction is sacrificed slightly. In this regard, by providing one cathode contact hole 20A corresponding to every three adjacent columns of sub-pixels 20, the resistance of the cathode 21 can be reduced, and the influence of the cathode contact hole 20A on a size of the printing area of the sub-pixel 20 can be reduced.

In other embodiments of the present application, referring to FIG. 10, FIG. 10 is a schematic diagram of an eighth plane structure of the display panel provided by the present application. The difference from the display panel 100 shown in FIG. 9 is that, in this embodiment of the present application, each repeating unit 200 is correspondingly provided with a cathode contact hole 21A. That is, the extension length of each cathode contact hole 21A along the first direction is equal to the extension length of the three adjacent sub-pixels 20.

Similarly, on the basis of reducing the cathode contact holes 20A and the auxiliary electrodes 22, the distribution uniformity of the cathode contact holes 20A and the auxiliary electrodes 22 can be maintained, and the display uniformity of the display panel 100 can be improved.

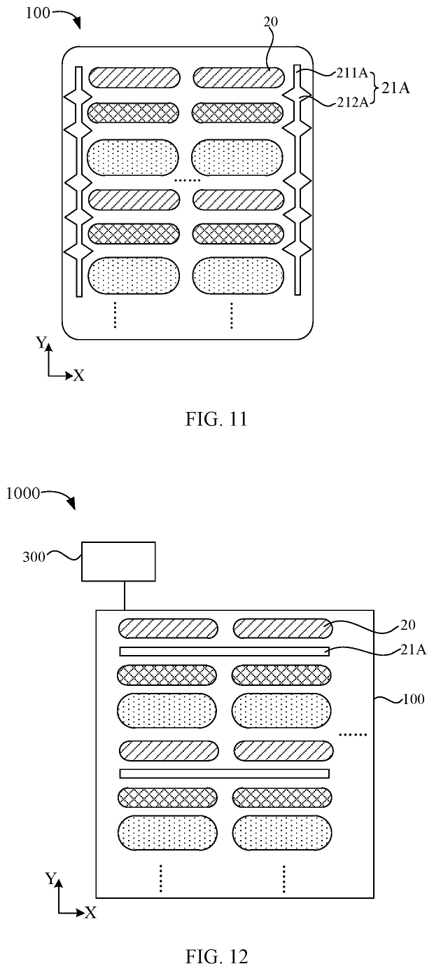

Referring to FIG. 11, FIG. 11 is a schematic diagram of a ninth plan structure of the display panel provided by the present application. The difference from the display panel 100 shown in FIG. 9 is that, in this embodiment of the present application, at least one cathode contact hole 21A includes a first portion 211A and at least a second portion 212A. The first portion 211A extends in the first direction. Each second portion 212A extends in the second direction from the first portion 211A. The second portion 212A is located between two adjacent columns of sub-pixels 20.

Similarly, without impacting a printing area, the area of the cathode contact hole 21A can be increased by arranging the second portion 212A at a gap between the adjacent sub-pixels 20. In this way, the extension length of the first portion 211A in the first direction can be reduced. While reducing the impedance of the cathode 21, the space occupied by the first portion 211A in the second direction is reduced, thereby improving pixel resolution.

The plane structure of the second portion 212A may be in the shape of a triangle, a circular arc, a rectangle, a trapezoid, etc. For details, please refer to the above-mentioned embodiments, which will not be repeated here. The plane structure of the second portion 212A can be designed according to the topography of the gap between adjacent sub-pixels 20, and the area of the cathode contact hole 21A can be increased without impacting the printing area.

In addition, the extension length of the second portion 212A along the first direction may not be limited, and may be designed according to the actual process.

Correspondingly, the present application also provides a display device, which includes a power chip and a display panel. The power chip is connected to the display panel to provide a common voltage to the cathode in the display panel. The display panel is the display panel described in any of the above-mentioned embodiments. Detail may be referred to the above-mentioned content, which will not be repeated herein for brevity.

In an embodiment of the present application, the display panel may be an organic light-emitting display panel or an inorganic quantum dot light-emitting display panel. The display device may be a smart phone, a tablet computer, a video player, a personal computer (PC), etc., which is not limited in the present application.

Specifically, referring to FIG. 12, FIG. 12 is a schematic structural diagram of a display device provided by the present application. The display device 1000 includes a display panel 100 and a power chip 300. The power chip 300 may be a power management integrated chip (PMIC). The power chip 300 can provide the power supply voltage required for the normal operation of the display panel 100. For example, the power chip 300 may provide a common voltage to the cathode of the display panel 100, so that the sub-pixels emit light normally.

In the display device 1000 of the present application, the cathode contact holes 21A are disposed between two adjacent rows of the sub-pixels 20, or the cathode contact holes 21A are disposed between two adjacent columns of the sub-pixels 20, the cathode contact holes are located close to the cathode contact holes, and the ends of the plurality of sub-pixels 20 that are close to the cathode contact hole 21A and located in the same column can be flush with the ends close to the cathode contact hole 21A, which effectively ensures the printing range corresponding to each sub-pixel 20 when inkjet printing is performed in the second direction, thereby improving the utilization rate of printing nozzles, reducing the inkjet printing time.

The display panel and the display device provided in the embodiments of the present application have been described in detail above. Specific examples are used in this document to explain the principles and implementation of the present invention. The descriptions of the above embodiments are only for understanding the method of the present invention and its core ideas, to help understand the technical solution of the present application and its core ideas, and a person of ordinary skill in the art should understand that it can still modify the technical solution described in the foregoing embodiments, or equivalently replace some of the technical features. Such modifications or replacements do not depart the spirit of the corresponding technical solutions beyond the scope of the technical solutions of the embodiments of the present application.

What is claimed is:

1. A display panel, comprising a cathode and an auxiliary electrode arranged in a layer different from the cathode, wherein the auxiliary electrode is electrically connected to the cathode through a corresponding one of cathode contact holes, the display panel further comprises a plurality of sub-pixels arranged in an array, an extension length of each of the sub-pixels along a first direction is less than an extension length of each of the sub-pixels along a second direction, and the second direction intersects the first direction; and
wherein one of the cathode contact holes is defined between at least two adjacent rows of the sub-pixels and extends along the second direction, or one of the cathode contact holes is located between at least two adjacent columns of the sub-pixels and extends along the first direction.

2. The display panel according to claim 1, wherein one of the cathode contact holes is located between at least two adjacent rows of the sub-pixels, and an extension length of each of the cathode contact holes along the second direction is equal to the extension length of at least one of the sub-pixels along the second direction.

3. The display panel according to claim 2, wherein at least one of the cathode contact holes comprises a first portion and at least one second portion, the first portion extends along the second direction, each of the second portion extends from the first portion along the first direction, and the second portion is located between adjacent ones of the columns of the sub-pixels.

4. The display panel according to claim 3, wherein a plane structure of the second portion has a shape of a triangle, a circular arc, a rectangle, or a trapezoid.

5. The display panel according to claim 1, wherein each of the sub-pixels corresponds to one of the cathode contact holes.

6. The display panel according to claim 1, wherein the sub-pixels are red sub-pixels, green sub-pixels, or blue sub-pixels; the red sub-pixels, the green sub-pixels, and the blue sub-pixels are repeatedly arranged in any combination as repeating units; and
each of the repeating units is correspondingly provided with one of the cathode contact holes.

7. The display panel according to claim 6, wherein an extension length of each of the red sub-pixels in the second direction, an extension length of each of the green sub-pixels in the second direction, and an extension length of each of the blue sub-pixels in the second direction are all equal, and the extension length of each of the red sub-pixels along the first direction is greater than the extension length of each of the green sub-pixels along the first direction length, the extension length of each of the blue sub-pixels along the first direction is greater than the extension length of each of the red sub-pixels along the first direction.

8. The display panel according to claim 7, wherein the cathode contact holes are disposed between the red sub-pixels and the green sub-pixels.

9. The display panel according to claim 7, wherein the cathode contact holes are disposed between the blue sub-pixels and the red sub-pixels, or the cathode contact holes are disposed in the blue sub-pixels and the green sub-pixels;
a side of each of the blue sub-pixels close to the cathode contact holes has a concave portion, and at least part of each of the cathode contact holes is disposed in the concave portion.

10. The display panel according to claim 1, wherein the cathode contact holes are located between at least two adjacent columns of the sub-pixels, and an extension length of each of the cathode contact holes along the first direction is equal to an extension length of each of the sub-pixels along the first direction.

11. The display panel according to claim 10, wherein at least one of the cathode contact holes comprises a first portion and at least one second portion, the first portion extends along the first direction, each of the second portion extends from the first portion along the second direction, and the second portion is located between adjacent ones of the columns of the sub-pixels.

12. The display panel according to claim 1, wherein an extension length of each of the cathode contact holes along the first direction is equal to an extension length of a row of the sub-pixels along the first direction, and one of the cathode contact holes is defined correspondingly in every adjacent three columns of the sub-pixels.

13. A display device, comprising a power supply chip and a display panel, wherein the display panel comprises a cathode and an auxiliary electrode arranged in a layer different from the cathode, wherein the auxiliary electrode is electrically connected to the cathode through a corresponding one of cathode contact holes, the display panel further comprises a plurality of sub-pixels arranged in an array, an extension length of each of the sub-pixels along a first direction is less than an extension length of each of the sub-pixels along a second direction, and the second direction intersects the first direction;
wherein one of the cathode contact holes is defined between at least two adjacent rows of the sub-pixels and extends along the second direction, or one of the cathode contact holes is located between at least two adjacent columns of the sub-pixels and extends along the first direction; and
wherein the power supply chip is connected to the display panel to provide a common voltage to the cathode.

14. The display device according to claim 13, wherein one of the cathode contact holes is located between at least two adjacent rows of the sub-pixels, and an extension length of each of the cathode contact holes along the second direction is equal to the extension length of at least one of the sub-pixels along the second direction.

15. The display device according to claim 14, wherein at least one of the cathode contact holes comprises a first portion and at least one second portion, the first portion extends along the second direction, each of the second portion extends from the first portion along the first direction, and the second portion is located between adjacent ones of the columns of the sub-pixels.

16. The display device according to claim 13, wherein each of the sub-pixels corresponds to one of the cathode contact holes.

17. The display device according to claim 13, wherein the sub-pixels are red sub-pixels, green sub-pixels, or blue sub-pixels; the red sub-pixels, the green sub-pixels, and the blue sub-pixels are repeatedly arranged in any combination as repeating units; and
each of the repeating units is correspondingly provided with one of the cathode contact holes.

18. The display device according to claim 17, wherein an extension length of each of the red sub-pixels in the second direction, an extension length of each of the green sub-pixels in the second direction, and an extension length of each of the blue sub-pixels in the second direction are all equal, and the extension length of each of the red sub-pixels along the first direction is greater than the extension length of each of the green sub-pixels along the first direction length, the extension length of each of the blue sub-pixels along the first direction is greater than the extension length of each of the red sub-pixels along the first direction.

19. The display device according to claim 18, wherein the cathode contact holes are disposed between the blue sub-pixels and the red sub-pixels, or the cathode contact holes are disposed in the blue sub-pixels and the green sub-pixels;
a side of each of the blue sub-pixels close to the cathode contact holes has a concave portion, and at least part of each of the cathode contact holes is disposed in the concave portion.

20. The display device according to claim 13, wherein the cathode contact holes are located between at least two adjacent columns of the sub-pixels, and an extension length of each of the cathode contact holes along the first direction is equal to an extension length of each of the sub-pixels along the first direction.
